(19) United States
(12) Patent Application Publication
(10) Pub. No.: US 2025/0266275 A1
(43) Pub. Date: Aug. 21, 2025

(54) AUTOMATED SEMICONDUCTOR WAFER TRANSFER MONITORING

(71) Applicant: Taiwan Semiconductor Manufacturing Company, LTD., Hsinchu (TW)

(72) Inventors: Chun-Ying Chien, New Taipei (TW); Ting-Hao Chang, Taichung (TW); Zi Xu Lin, Taipei (TW); Wen-Chi Chien, Toufen (TW); Chun-Wei Chang, New Taipei (TW)

(21) Appl. No.: 18/581,750

(22) Filed: Feb. 20, 2024

(51) Int. Cl. H01L 21/67; G01N 29/44

(52) U.S. Cl. CPC H01L 21/67288; G01N 29/4436; G01N 29/4445; G01N 29/4481; G01N 2291/2697

(57) ABSTRACT

Semiconductor wafer transfer monitoring includes measuring vibration of a component during a transfer of a semiconductor wafer. The measured vibration is analyzed to detect a collision or scratching of the semiconductor wafer during the transfer. At least one remedial action is performed in response to the detection of the collision or scratching of the semiconductor wafer, such as outputting a notification of the collision or scratching, or stopping the transfer of the semiconductor wafer. The component whose vibration is measured may be a wafer transfer robot used in the transfer. The analysis of the measured vibration may include inputting the measured vibration to an artificial intelligence (AI) algorithm trained to detect the collision or scratching of the semiconductor wafer.

### BACKGROUND

The following relates to the semiconductor fabrication arts, semiconductor wafer transfer arts, and related arts.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates a semiconductor wafer transfer monitoring apparatus in conjunction with a semiconductor wafer transfer apparatus.

FIG. 2 diagrammatically illustrates an automated semiconductor wafer transfer monitoring method.

FIGS. 3 and 4 diagrammatically present some vibration patterns that may be characteristic of various problems.

FIG. 5 diagrammatically illustrates another nonlimiting illustrative embodiment of a vibration analysis for an automated semiconductor wafer transfer monitoring method.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In a semiconductor foundry, batches of wafers are commonly transferred in a wafer carrier, such as a front-opening unified pod (FOUP) that is designed to be compatible with a range of different semiconductor processing or characterization tools. In a typical semiconductor wafer processing workflow for manufacturing integrated circuits (ICs), a semiconductor processing or characterization tool (generically referred to herein as a “tool”) includes a load port. An overhead transport (OHT) or other automated transportation system delivers a FOUP or other wafer carrier to the load port of the tool, and a wafer transfer robot transfers semiconductor wafers between the FOUP or other wafer carrier and the tool for processing or characterization. By way of some nonlimiting illustrative examples, the semiconductor processing or characterization tool of a foundry may include plasma etching tools, chemical vapor deposition (CVD) and/or physical vapor deposition (PVD) tools, photoresist spinners, photoresist developer tools, microscopy tools, and/or so forth.

This type of automated workflow has numerous advantages, such as increasing wafer throughput, ensuring uniform processing of all semiconductor wafers of a batch, reducing incidents of wafer damage due to mishandling, and reducing wafer contamination from human foundry workers. However, automated wafer transfer can suffer from various types of malfunctions, such as wafer collision with the FOUP or other wafer carrier or with the tool, scratching of a wafer during transfer, oblique insertion or removal of a semiconductor wafer being transferred by the semiconductor wafer transfer, and/or so forth. While the incidents of automated wafer transfer malfunctions is typically low, such transfer malfunctions can result in scrapping of wafers or other type of IC yield reduction, and can also damage expensive precision foundry equipment.

Furthermore, when an automated wafer transfer malfunction does occur, it is sometimes caused by a systematic problem with the wafer transfer apparatus, such as a misalignment between the wafer transfer robot and the load port. In such a case, continued operation of the automated wafer transfer system will damage every wafer handled by the wafer transfer robot until the problem is identified. If there is a significant delay between when the problem arises and when it is identified, this can result in a large cost due to damage to a succession of wafers.

One way to identify a problem with a wafer transfer is by analysis of the wafer to detect damage to the wafer caused by the problem with the wafer transfer. This analysis can be challenging, as damage sufficient to require scrapping a semiconductor wafer undergoing IC manufacturing may be visually indetectable. Hence, an automated wafer defect inspection system may be inserted into the IC fabrication workflow at strategic points in the workflow. The defect inspection system may employ technologies such as electron beam (e-beam) inspection to detect wafer defects that are not visible to the human eye (but which can nonetheless require scrapping of the wafer). However, this approach will not identify a wafer transfer problem at the time it occurs. Rather, it will only identify a problem with the wafer at a later point in the workflow where the defect inspection system is applied-and even then, forensic analysis to identify the root cause of the problem with the wafer as a wafer transfer problem may be tedious and time consuming. Similarly, offline particle or photoresist monitoring may detect a problem, but again this will occur at some point downstream from the root cause wafer transfer problem in the IC manufacturing workflow; and again, tedious and time consuming forensic analysis will be involved in identifying the root cause as a wafer transfer problem.

Disclosed herein are various embodiments of semiconductor wafer transfer monitoring apparatuses and methods that provide for direct and virtually instantaneous detection of a problem with a wafer transfer. The disclosed approaches include disposing or operatively connecting a vibration sensor to measure vibration data of the wafer transfer robot or another component of the semiconductor wafer transfer apparatus during a semiconductor wafer transfer performed by the semiconductor wafer transfer apparatus. An electronic processor is programmed to analyze the measured vibration data to detect a problem with the semiconductor wafer transfer, and to perform at least one remedial action in response to detection of the problem with the semiconductor wafer transfer.

As a mechanical system including servomotors and numerous moving components, a semiconductor wafer transfer apparatus typically exhibits a significant amount of vibration during normal operation. Hence, the detection of vibration does not, by itself, demonstrate a wafer transfer problem. However, as disclosed herein, by suitable analysis measured vibration caused by a wafer transfer problem can be distinguished from vibration produced by the wafer transfer apparatus during its normal operation. Even further, in some embodiments disclosed herein the type of wafer transfer problem (e.g., a collision versus formation of a wafer scratch versus oblique insertion or withdrawal of a wafer) can be distinguished by analysis of the measured vibration.

The disclosed semiconductor wafer transfer monitoring apparatuses and methods have numerous advantages. They provide nearly instantaneous detection of a wafer transfer problem, with the wafer transfer problem being detected as it occurs or immediately thereafter, and before the wafer transfer is completed. This enables remedial action to be taken immediately, such as by stopping the wafer transfer. This can prevent a malfunctioning wafer transfer operation from continuing to a point where expensive damage to the wafer transfer apparatus may occur.

A further advantage of the disclosed wafer transfer monitoring apparatuses and methods is that the stoppage of the wafer transfer operation (or, in some embodiments, immediate notification thereof to foundry workers) in immediate response to detection of a wafer transfer problem can ensure the source of the wafer transfer problem is identified and fixed before further semiconductor wafers are handled by the wafer transfer apparatus. This can limit the cost of the malfunction of the wafer transfer apparatus to the scrapping of (at most) a single semiconductor wafer. Indeed, near-instantaneous detection of a wafer transfer problem and immediate stoppage of the wafer transfer may even enable the subject wafer itself to be at least partially saved. For example, if the real-time wafer transfer monitoring disclosed herein detects the start of an abrasion causing formation of a wafer scratch and immediately stops the wafer transfer, then only that portion of the wafer at or near the incipient wafer scratch may be lost.

A further advantage of the disclosed wafer transfer monitoring apparatuses and methods is that the wafer transfer problem is directly detected. Unlike approaches which rely on subsequent detection of damage to the wafer and forensic analysis to trace the source of the damage back to a wafer transfer problem, the disclosed wafer transfer monitoring apparatuses and methods directly identify a problem with a wafer transfer, and in some embodiments even identify the type of problem (e.g., collision, scratch formation, oblique wafer insertion or removal, et cetera).

A further advantage of the disclosed wafer transfer monitoring apparatuses and methods is that they introduce no additional steps in the IC fabrication process workflow. For example, the disclosed wafer transfer monitoring apparatuses and methods do not entail an additional wafer inspection step.

Still yet a further advantage of the disclosed wafer transfer monitoring apparatuses and methods is that they are readily retrofitted to an existing semiconductor wafer transfer apparatus. For example, in some embodiments the vibration sensor is battery-powered and includes a wireless transmitter or transceiver for sending measured vibration data to a computer or other electronic processor that performs the vibration analysis. In this case, the retrofit merely entails attaching the battery-powered wireless vibration sensor to the wafer transfer robot or another suitable component of the wafer transfer apparatus and loading suitable vibration data acquisition and analysis software onto a computer of the semiconductor foundry.

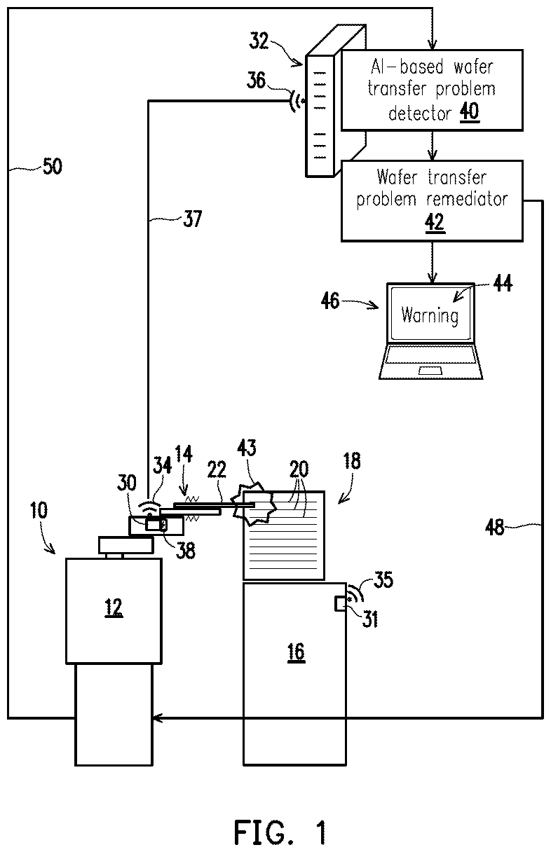

With reference now to FIG. 1, semiconductor wafer transfer monitoring apparatus is shown in conjunction with a monitored wafer transfer apparatus.

The illustrative wafer transfer apparatus of FIG. 1 for transferring wafers to and from a semiconductor processing or characterization tool (i.e., “tool”, not shown in FIG. 1) includes a wafer transfer robot 10 having a base 12 and a robotic arm 14. The robotic arm 14 can comprise horizontally sliding segments, as shown, or can be a more complex articulated robotic arm with multiple joints, or so forth. The wafer transfer apparatus further includes a load port 16 having a socket or the like sized and shaped to receive an illustrative front-opening unified pod (FOUP) 18 or other wafer carrier. In a semiconductor foundry, an overhead transport (OHT, not shown) or other automated transportation system delivers the FOUP 18 (or other wafer carrier) to the load port 16 of the tool and, after processing or characterization of the semiconductor wafers carried by the FOUP 18, removes the FOUP 18 from the load port 16 (typically to deliver the FOUP to the next tool of the foundry in the IC processing workflow). As shown, the FOUP 18 includes a set of slots 20 each sized and shaped to receive and hold a semiconductor wafer. The FOUP 18 can carry as many semiconductor wafers as it has slots 20, and the set of wafers carried by the FOUP 18 may in some nomenclatures be referred to as a wafer batch. Illustrative FIG. 1 illustrates a single semiconductor wafer 22 which is in the process of being removed from (or, viewed alternatively, inserted into) a slot 20 of the FOUP 18. After removing the wafer 22 from the FOUP 18, the wafer transfer robot 10 then moves the wafer to the tool (not shown) and loads it into the tool for processing or characterization. After the processing or characterization is complete, the wafer transfer robot 10 removes the semiconductor wafer from the tool and moves the wafer back to the FOUP 18 and inserts it into an open slot 20 of the FOUP 18.

It will be appreciated that successful removal of the wafer 22 from a slot 20 of the FOUP 18 and subsequent (re-) insertion of the wafer into a slot 20 of the FOUP 18 requires a suitably precise alignment between the wafer transfer robot 10 and the FOUP 18 disposed on the port 16. Likewise, although not shown it will be further appreciated that successful insertion of the wafer 22 into the tool and subsequent removal of the wafer from the tool requires a suitably precise alignment between the wafer transfer robot 10 and the tool. Such alignment is typically initially achieved by a manual process in which the various components 12, 16 are leveled, height-adjusted, rotated, and/or so forth. Thereafter, alignment can generally be expected to be maintained for an extended period of time. However, numerous mechanisms can result in the wafer transfer apparatus (or a component thereof) going out of alignment to the extent that a problem with a wafer transfer operation can arise. Such misalignment can be introduced in various ways such as due to seismic activity, settling of the various components (for example, the wafer transfer robot 10 can be a heavy component that can gradually shift its position over time due to gravity), movement of components due to vibrations introduced during normal operation of the wafer transfer robot 10 or other components, vibrations produced by normal operation of the semiconductor processing or characterization tool, human involvement (e.g., a foundry worker bumping into the wafer transfer robot 10), and/or so forth. Moreover, a problem with a particular wafer transfer could arise due to a structural flaw in the FOUP 18, such as a bent slot 20 or a semiconductor wafer that arrives placed in the slot 20 in an incorrect (oblique) position. These are merely some nonlimiting illustrative examples of some possible root causes for a wafer transfer problem.

It is also noted that the illustrative wafer transfer apparatus including the illustrative wafer transfer robot 10 and load port 16 are merely nonlimiting illustrative examples. More generally, a given wafer transfer apparatus can include a wide range of mechanisms for transferring semiconductor wafers, such as sliding mechanisms (as shown in the robotic arm 14), articulated arm mechanisms, moving railways, tracks, or the like, and/or so forth. In general, the wafer transfer apparatus includes mechanical moving parts, typically driven by motors (servomotors, stepper motors, and/or so forth) driving mechanical linkages, tracks, arms, and/or the like to remove a semiconductor wafer from a wafer carrier, transfer the wafer to a semiconductor processing or characterization tool, insert the wafer into the tool for processing or characterization, and then perform the process in reverse to return the wafer to the wafer carrier. In some more complex workflow setups (not shown), a first wafer transfer apparatus may transfer the wafer from the wafer carrier to a first tool, a second wafer transfer apparatus may transfer the wafer directly from the first tool to a second tool, and a third wafer transfer apparatus may transfer the wafer from the second tool back to the wafer carrier. Such extended workflow setups can be extended to incorporate three or even more tools, and in some cases the various wafer transfer apparatuses may be configurable to transfer a wafer in a programmed sequence between two, three, or more tools of a tool cluster. These are merely further nonlimiting examples. The semiconductor wafer transfer monitoring apparatuses and methods disclosed herein can be utilized to monitor any such wafer transfer apparatus.

With continuing reference to FIG. 1, an illustrative semiconductor wafer transfer monitoring apparatus includes a vibration sensor 30 and a computer or other electronic processor 32. The vibration sensor 30 is operatively connected to measure vibration data of the wafer transfer robot 10 or another component of the semiconductor wafer transfer apparatus (e.g., the load port 16, as illustrated in FIG. 1 by an alternative vibration sensor 31) during a semiconductor wafer transfer performed by the semiconductor wafer transfer apparatus. The illustrative vibration sensor 30 is mounted to a component of the robotic arm 14 of the wafer transfer robot 10. This placement of the vibration sensor 30 has certain advantages. The wafer transfer robot 10, and more particularly its robotic arm 14, is involved in every stage of the wafer transfer process (e.g., removing the wafer from the FOUP 18 transferring it to the tool, and inserting the wafer into the tool; and the reverse process to return the wafer to the FOUP 18). The wafer transfer robot 10, and especially its robotic arm 14, is also likely to experience strong vibration in response to a problem such as a wafer collision, wafer scratch formation, or oblique insertion or removal of the wafer 22 into or from a slot 20 of the FOUP 18. This is because the robotic arm 14 is directly carrying the semiconductor wafer 22.

However, other operative connections of the vibration sensor 30 to measure the vibration data are contemplated. For example, the vibration sensor could be disposed on the base 12 of the wafer transfer robot 10, or could be disposed on the load port 16. An advantage of disposing the vibration sensor on the load port 16 is that it would be highly sensitive to vibration caused by misplacement of the FOUP 18 onto the load port 16, which can be a source of a wafer transfer problem. Placement of the vibration sensor on the base 12 of the wafer transfer robot 10 could have certain advantages in mechanically filtering out normal vibrations of the robotic arm. It is also noted that while FIG. 1 illustrates a single vibration sensor 30 mounted on the robotic arm 14 of the wafer transfer robot 10, it is contemplated to include two or more vibration sensors mounted on different components of the wafer transfer apparatus to increase the sensitivity and/or types of wafer transfer problems that can be detected. For example, adding a second vibration sensor disposed on the load port 16 could facilitate detection of misplacement of the FOUP 18 on the load port 16 at the time of that misplacement. By contrast, if only the single illustrative vibration sensor 30 disposed on the robotic arm 14 is provided then such FOUP misplacement would only be detected when the robotic arm 14 fails to cleanly withdraw a wafer from a slot 20 of the FOUP 18.

The vibration sensor 30 can be any type of sensor that produces an output in response to vibrations. In some embodiments, the vibration sensor 30 comprises an accelerometer (e.g., a three-dimensional accelerometer). In such embodiments, the accelerometer-based vibration sensor 30 detects vibrations due to the accelerations such vibrations apply to the accelerometer of the vibration sensor 30, which the accelerometer-based vibration sensor 30 converts to an electric signal. In other embodiments, the vibration sensor 30 may comprise a piezoelectric crystal. In such embodiments, the vibration imparts mechanical stress to the piezoelectric crystal which acts as a transducer to convert the stress to an electric signal. In other embodiments, the vibration sensor 30 may comprise an eddy current or capacitive displacement sensor. In such embodiments, the vibration induces eddy currents or causes cyclical variation in the spacing of conductors of a capacitive displacement sensor, thus converting the vibrations to an electric signal. In other embodiments, the vibration sensor 30 may comprise a laser displacement-based vibration sensor, in which vibration varies a light path of a laser/optical detector pair to convert the vibration to an electric signal. Still further contemplated embodiments of the vibration sensor 30 include a strain gauge-based vibration sensor, an acoustic vibration sensor, a gyroscopic vibration sensor, or so forth. These are merely some nonlimiting illustrative examples of some suitable embodiments of the vibration sensor 30, and more generally the vibration sensor 30 can employ any suitable transducer technology operative to convert vibration to an electrical signal.

The illustrative electronic processor 32 is a computer 32; however, another electronic processor such as a microprocessor-equipped electronic controller or the like is also contemplated. The computer 32 is suitably programmed as disclosed herein to analyze vibration data acquired by the vibration sensor 30 to detect a problem with a wafer transfer performed by the wafer transfer apparatus 10, 16, such as a wafer collision, wafer scratch formation, oblique insertion/removal of the wafer, or so forth.

To cooperatively operate, the vibration data acquired by the vibration sensor 30 is transferred to the electronic processor 32 for analysis. In the illustrative embodiment, this is accomplished by a wireless transmitter or transceiver 34 connected with or integral with or in operative communication with the vibration sensor 30 (and/or an analogous wireless transmitter or transceiver 35 connected with or integral with or in operative communication with the additional or alternative vibration sensor 31), and a wireless receiver or transceiver 36 connected with or integral with or in operative communication with the electronic processor 32. The wireless transmitter or transceiver 34 and the wireless receiver or transceiver 36 suitably utilize a common wireless communication protocol, such as Bluetooth™, WiFi™, Zigbee™, or so forth, to transmit vibration data 37 from the vibration sensor 30 to the electronic processor 32. In some embodiments, a low power protocol such as low power Bluetooth™ or Zigbee™ is advantageously used to minimize the power draw for transmission at the vibration sensor 30. In such embodiments, the vibration sensor 30 may be battery-powered, as diagrammatically indicated in FIG. 1 by an illustrative battery 38. While FIG. 1 diagrammatically shows the wireless transmitter or transceiver 34 and battery 38 as separate components from the vibration sensor 30, in some embodiments the transmitter or transceiver 34 and battery 38 may be integral with the vibration sensor 30, e.g., there may be a single housing which houses the accelerometer, piezoelectric crystal, or other vibration-sensing component of the vibration sensor 30 and also houses the transmitter or transceiver 34 and battery 38, so that the combination 30, 34, 38 is constructed as a single unitary wireless, battery-powered vibration sensor 30. In such cases, the wireless, battery-powered vibration sensor 30 is a standalone unit that is physically attached to the robotic arm 14 of the wafer transfer robot 10 by an adhesive, by fasteners (e.g., screws, bolts, et cetera), using tape, or the like. This facilitates retrofitting the wafer transfer apparatus 10, 16 with the wafer transfer monitoring apparatus as there are no electrical connections between the wafer transfer monitoring apparatus and the wafer transfer apparatus 10, 16 and the securing of the vibration sensor 30 to the wafer transfer apparatus 10, 16 does not entail substantive modifications to the latter.

While the illustrative embodiment employs wireless communication between the vibration sensor 30 and the electronic processor 32, a wired connection is also contemplated. Likewise, while a battery powered vibration sensor 30, 38 is illustrated, it is alternatively contemplated for the vibration sensor to be powered by a wired power connection (e.g., connecting to a.c. electrical power of the foundry, for example). As another contemplated example, in a non-retrofit situation the vibration sensor 30 could be integrated into the wafer transfer robot (e.g., housed within the housing of a component of the robot), and in such an implementation the vibration sensor could draw power from the robot itself and could interface with a wired or wireless communication interface of the robot to send vibration data to the electronic processor 32. In an even more tightly integrated configuration, the electronic processor 32 could be implemented in a microprocessor-based built-in robot controller of the wafer transfer robot, so that the wafer transfer monitoring apparatus is fully integrated with the wafer transfer robot.

As previously noted, the electronic processor 32 is programmed to perform an analysis 40 of the measured vibration data received from the vibration sensor 30 (e.g., via wireless communication components 34 and 38 in the illustrative example of FIG. 1) to detect a problem with the semiconductor wafer transfer, and to implement a wafer transfer problem remediator 42 to perform at least one remedial action in response to detection of the problem with the semiconductor wafer transfer. For example, in one nonlimiting illustrative example of the analysis 40, the electronic processor 32 may be programmed to analyze the measured vibration data to detect a problem with the semiconductor wafer transfer by comparing the measured vibration data with reference vibration data representing successful semiconductor wafer transfer. In FIG. 1 a wafer transfer problem is diagrammatically indicated by a diagrammatically indicated collision 43 between the semiconductor wafer 22 and a slot 20 of the FOUP 18.

The analysis 40 of the measured vibration data to detect a wafer transfer problem can employ various approaches. This analysis is challenging, because as previously noted the wafer transfer apparatus 10, 16 typically undergoes normal vibrations during normal operation of the wafer transfer apparatus 10, 16, due to operation of servomotors, stepper motors, or the like, normal contact between the wafer 22 and components such as the slot 20 of the FOUP 18 or a wafer receptacle of the semiconductor processing or characterization tool, mechanical movement of the robotic arm 14, and/or so forth. Vibration may also be present from other sources such as vacuum pumps or other components of the tool or so forth. Hence, in the illustrative embodiment, the analysis 40 is implemented as an artificial intelligence (AI) based wafer transfer problem detector 40. An AI algorithm or classifier such as an artificial neural network (ANN), a support vector machine (SVM) classifier, or other AI algorithm or classifier can be trained to distinguish vibration caused by a collision, scratch formation, oblique wafer placement, or the like from normal vibration that normally occurs during normal operation of the wafer transfer apparatus 10, 16. While an AI algorithm or classifier is used in the illustrative analysis 40, other types of analysis to detect a wafer transfer problem are contemplated, such as for example deriving features of the vibration (e.g., vibration amplitude metrics, frequency metrics, et cetera) and determining whether there is a wafer transfer problem based on these vibration metrics.

In some embodiments, the remedial action 42 performed in response to detection of a problem with the wafer transfer includes issuing a warning or notification 44 (these terms being used synonymously herein) on a suitable output device 46, such as an illustrative computer or workstation 46. The warning or notification 44 can be a textual notification stating the detected wafer transfer problem in words, for example. Additionally or alternatively, the warning or notification 44 is output to an IC fabrication process workflow log.

In some embodiments, the remedial action 42 performed in response to detection of a problem with the wafer transfer additionally or alternatively includes stopping the wafer transfer operation being performed by the wafer transfer apparatus 10, 16. In some embodiments, this is performed by sending an abort or stop transfer signal 48 from the electronic processor 32 to the wafer transfer robot 10 (in the illustrative example; or, more generally, to a control component of the wafer transfer apparatus) causing the wafer transfer apparatus to immediately stop the wafer transfer. As previously noted, such an immediate stoppage of the wafer transfer in response to detecting a problem with the wafer transfer can minimize damage to hardware of the wafer transfer apparatus, and may even enable the wafer 22 undergoing the transfer to be wholly or partly salvaged.

In the examples described thus far, the wafer transfer problem detector 40 performs an analysis which operates solely on vibration data provided by the vibration sensor 30. In some embodiments, the vibration data is the sole input for detecting a problem with the wafer transfer.

With continuing reference to FIG. 1, in other embodiments the wafer transfer problem detector 40 performs an analysis which operates on the vibration data provided by the vibration sensor 30, and which also operates on control data 50 relating to the semiconductor wafer transfer being performed by the wafer transfer apparatus 10, 16. For example, the control data 50 may be provided by the wafer transfer robot 10. If such control data 50 are provided, this additional information can be useful for better discriminating between vibrations caused by a wafer transfer problem and normal vibrations. Additionally or alternatively, the control data 50 can be useful for classifying the type of wafer transfer problem. For example, if the vibration identified as indicative of a wafer transfer problem occurs while the control data 50 indicates the wafer is being removed from the FOUP 18, then the wafer transfer problem may be classified as relating to abnormal contact between the wafer 22 and the slot 20 of the FOUP 18. As another example, if the vibration identified as indicative of a wafer transfer problem occurs while the control data 50 indicates the wafer is being loaded into the semiconductor processing or characterization tool, then the wafer transfer problem may be classified as relating to abnormal contact between the wafer 22 and the tool.

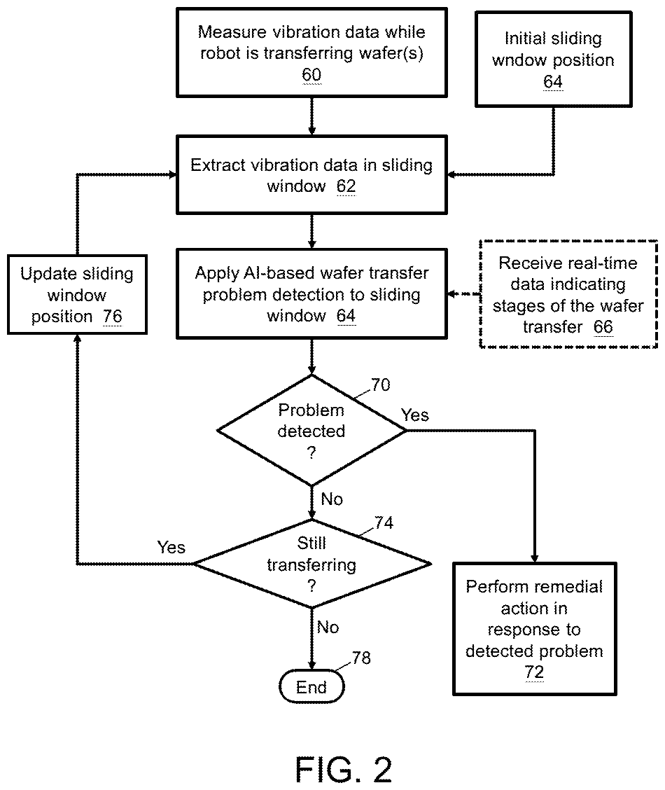

With reference now to FIG. 2, an illustrative wafer transfer monitoring method is described. This method may, for example, be performed by the wafer transfer monitoring apparatus of FIG. 1 (e.g., by the vibration sensor 30 and electronic processor 32). In an operation 60, vibration data is measured by the vibration sensor 30 while the wafer transfer robot 10 performs a wafer transfer. In an operation 62, vibration data are extracted in a sliding window. In an operation 64, AI-based wafer transfer problem detection is applied to the vibration data in each window of vibration data extracted in the operation 62. For example, the operation 64 may use the AI based wafer transfer problem detector 40 previously described.

Optionally, in an operation 66 real-time data is received indicating the current stage of the wafer transfer. For example, the operation 66 may receive control data 50 provided by the wafer transfer robot 10. The control data 50 is suitably time stamped or otherwise temporally aligned with the vibration data in each window of vibration data. In embodiments employing the optional operation 66, this received real-time data indicating the current stage of the wafer transfer is utilized in the operation 64 to improve the accuracy and/or classification of wafer transfer problems. In one approach, the real-time data indicating the current stage of the wafer transfer (or the current stage extracted from the real-time data) may be input to the AI based wafer transfer problem detector 40 along with the vibration data in the window, and the AI based wafer transfer problem detector 40 is trained to operate on the combination of the vibration data and this additional data.

In another approach, the AI based wafer transfer problem detector 40 operates only on the vibration data, and if a problem with the semiconductor wafer transfer is detected by the AI based wafer transfer problem detector 40 then the real-time data indicating the current stage of the wafer transfer (or the current stage extracted from the real-time data) is applied to classify the type of problem based on the wafer transfer stage at which it occurred.

In an operation 70, a determination is made whether a wafer transfer problem is detected, based on the output of the operation 64. If a wafer transfer problem is detected at the operation 70, then flow passes to operation 72 where a suitable remedial action is performed. The remedial action may include presenting a human-perceptible warning of the collision (e.g., as a real-time alert displayed on a controller display, and/or as a log entry in a workflow monitoring system, and/or so forth). If the AI based wafer transfer problem detector 40 (or optional subsequent analysis using the real-time data indicating the current stage of the wafer transfer) determines the type of wafer transfer problem, then the output human-perceptible warning may also include this information on the type of wafer transfer problem that has been detected.

The remedial action performed at the operation 72 may additionally or alternatively include stopping the wafer transfer, for example by sending an abort or stop transfer signal 48 from the electronic processor 32 to the wafer transfer robot 10 (in the illustrative example; or, more generally, to a control component of the wafer transfer apparatus) causing the wafer transfer apparatus to immediately stop the wafer transfer.

On the other hand, if a wafer transfer problem is not detected at the operation 70, then flow passes to an operation 74 where it is determined whether a wafer transfer is still in progress. If so, then flow passes to an operation 76 which updates the sliding window position (e.g., by incrementing the sliding window in time by a temporal interval that is smaller than the total temporal width of the sliding window) and flow then passes back to operation 62 to analyze the next sliding window of vibration data. On the other hand, if the operation 74 determines the wafer transfer is complete, then the illustrative wafer transfer monitoring method of FIG. 2 terminates at stop 78.

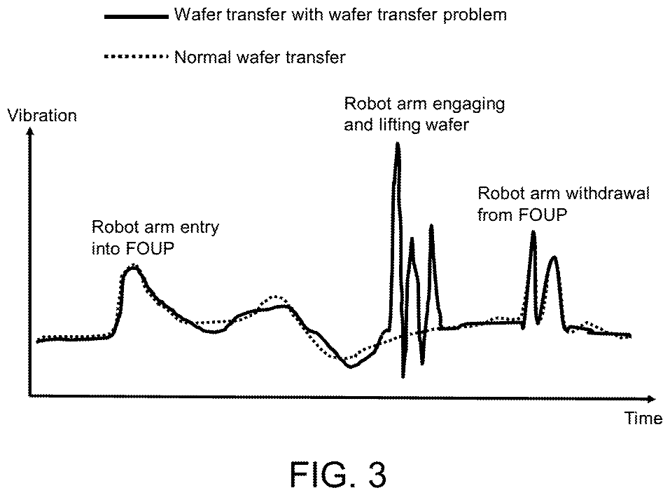

With reference to FIG. 3, a diagrammatic plot is shown of vibration versus time for a normal wafer transfer (dotted line) versus a wafer transfer with a problem (solid line). It is noted that FIG. 3 is not plotting measured experimental data, but rather diagrammatically depicts some possible general features of vibration data in the normal versus problem cases. The diagrammatic example of FIG. 3 illustrates that in the normal wafer transfer, the operation of the robot arm 14 engaging and lifting the wafer produces weak vibrations (dotted line); whereas, a wafer transfer problem in the form of an impact event during this operation produces large-amplitude vibration, as seen in the wafer transfer with wafer transfer problem (solid line).

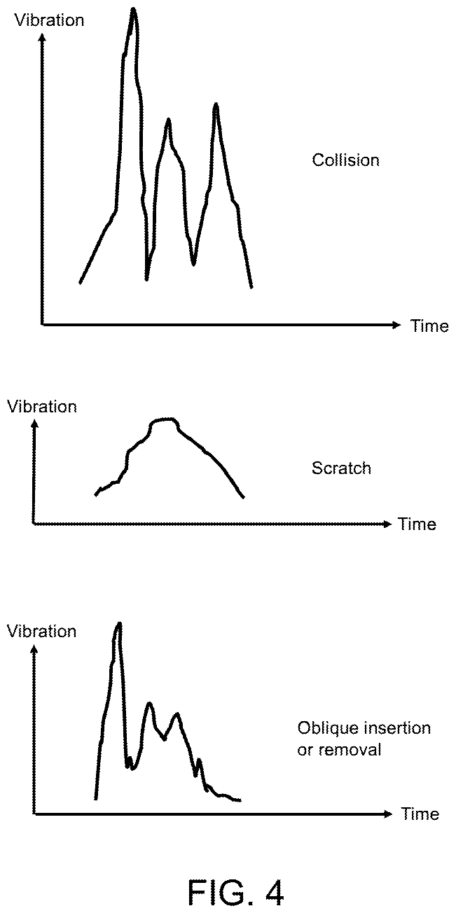

With reference to FIG. 4, diagrammatic plots are shown of some further nonlimiting illustrative vibration patterns that may occur during a problem with a semiconductor wafer transfer. As with FIG. 3, it is noted that FIG. 4 is not plotting measured experimental data, but rather is diagrammatically depicting some possible features of vibration data that may be indicative of certain types of problems with a semiconductor wafer transfer. FIG. 4 diagrammatically depicts nonlimiting possible vibration patterns for cases of: a collision of a semiconductor wafer being transferred by the semiconductor wafer transfer (top plot); a scratch being formed in the wafer (middle plot); and an oblique insertion of the wafer into a slot 20 of the FOUP 18 (bottom plot). The collision produces large amplitude vibrations indicative of an abrupt impact event. The scratch event produces smaller amplitude but higher frequency vibrations as the element producing the scratch lightly drags across the surface of the wafer. The oblique insertion event produces a high amplitude initial vibration as the wafer obliquely contacts the slot (or, conversely, a well-positioned wafer contacts an obliquely warped slot), but this vibration rapidly decays as the wafer enters the slot which can have the effect of dampening the vibration.

The examples of FIGS. 3 and 4 are merely nonlimiting illustrative examples of some possible types of vibration data that may be indicative of certain types of problems with the wafer transfer. The specific vibration pattern characterizing a particular problem with a semiconductor wafer transfer may depend on numerous factors, such as: the type of vibration sensor; the placement of the vibration sensor 30 on the robot 10 (or other operative connection of the vibration sensor 30 to measure the vibration data of a component of the semiconductor wafer transfer apparatus during the wafer transfer); the type of semiconductor wafer transfer apparatus; the size of the wafer being transferred; the amount of vibration dampening employed with the semiconductor wafer transfer apparatus; various combinations thereof; and/or so forth. To accommodate such implementation-specific problem vibration patterns, the AI-based wafer transfer problem detector 40 is suitably trained on labeled training data generated by the specific implementation for which the detector 40 is to be used; or is suitably trained on labeled training data generated by a sufficiently similar implementation (or implementations) to the implementation for which the detector 40 is to be used. In the latter case, the sufficiently similar implementation(s) which generate the training data may, for example, employ the same make and model of semiconductor wafer transfer apparatus being employed to transfer wafers of the same size, and using the same type of vibration sensor mounted on the robot in the same position, as the implementation for which the detector 40 is to be used.

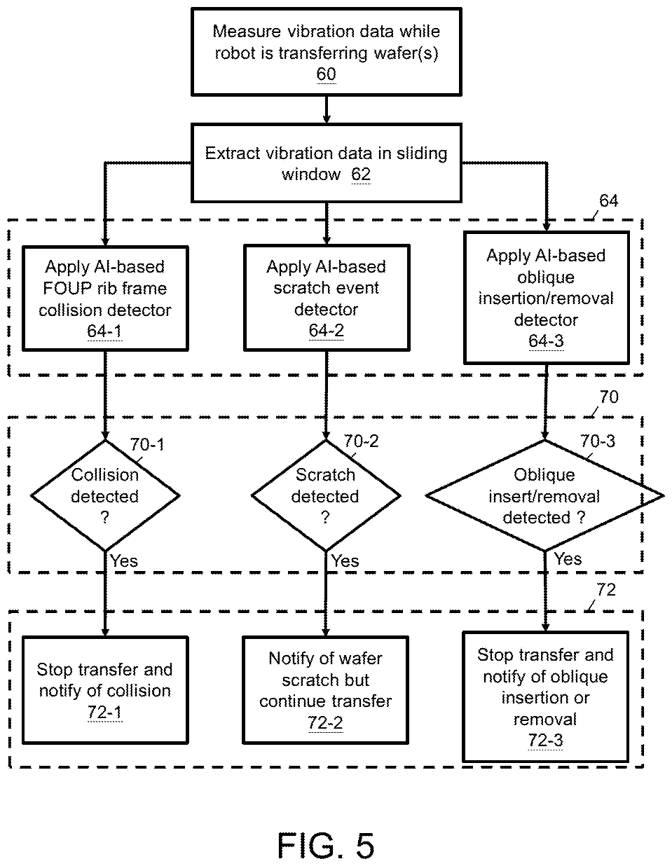

With returning reference to FIGS. 1 and 2, and with further reference now to FIG. 5, a more specific nonlimiting illustrative example of the operations 64 and 70 are described. FIG. 5 depicts the measurement and sliding window extraction operations 60 and 62 for context, which operate as previously described for these operations in FIG. 2. In the more specific example of FIG. 5, the AI-based wafer transfer problem detection operation 64 is implemented using three constituent AI-based wafer transfer problem detection operations 64-1, 64-2, and 64-3. The AI-based wafer transfer problem detection operations 64-1 employs an AI algorithm trained to detect a wafer transfer problem which is a collision of the wafer with the rib frame of the FOUP 18. The AI-based wafer transfer problem detection operations 64-2 employs an AI algorithm trained to detect a wafer transfer problem which is a wafer scratch event. The AI-based wafer transfer problem detection operations 64-3 employs an AI algorithm trained to detect oblique insertion or removal of a wafer into or from the FOUP 18.

It will be appreciated that the illustrative three constituent AI-based wafer transfer problem detection operations 64-1, 64-2, and 64-3 are examples, and more generally the number of constituent AI-based wafer transfer problem detection operations may be two, three, four, or more. Furthermore, the constituent AI-based wafer transfer problem detection operations may be trained to detect different types of problems in addition to and/or instead of the examples of the illustrative three constituent AI-based wafer transfer problem detection operations 64-1, 64-2, and 64-3.

The three constituent AI-based wafer transfer problem detection operations 64-1, 64-2, and 64-3 are each binary classifiers which output a first value (e.g., “1”) if the problem for which the AI algorithm is trained is detected, or a second value (e.g., “0”) if that problem is not detected. Alternatively, it is contemplated to replace the illustrative multiple binary classifiers 64-1, 64-2, and 64-3 with a single multiple-output classifier having an output for each type of problem.

With continuing reference to FIG. 5, in this illustrative example the problem determination operation 70 of the method of FIG. 2 is similarly constructed as three constituent decision operations 70-1, 70-2, and 70-3. The decision operation 70-1 determines whether a collision of the wafer with the rib frame of the FOUP 18 has been detected by the AI-based wafer transfer problem detection operation 64-1. The decision operation 70-2 determines whether a wafer scratch event has been detected by the AI-based wafer transfer problem detection operation 64-2. The decision operation 70-3 determines whether oblique insertion or removal of a wafer into or from the FOUP 18 has been detected by the AI-based wafer transfer problem detection operation 64-3.

The remediation operation 72 of the method of FIG. 2 is similarly constructed in the example of FIG. 5 as three constituent remediation actions 72-1, 72-2, and 72-3. The remediation 72-1 is operative in response to a determination that a collision of the wafer with the rib frame of the FOUP 18 has occurred, and includes stopping the wafer transfer and outputting a notification of the detection. The remediation of stopping the wafer transfer immediately is appropriate since continuing the transfer during/after a collision has a high likelihood of destroying the wafer and potentially damaging the wafer transfer semiconductor wafer transfer apparatus.

By contrast, the remediation 72-2 is operative in response to a determination that a wafer scratch event has occurred, and includes outputting a notification of the wafer scratch detection but does not also include stopping the wafer transfer. Not stopping the wafer transfer immediately may be an appropriate remediation to a wafer scratch event as it is typically less of an impact and the scratch event is less likely to destroy the wafer or damage the wafer transfer semiconductor wafer transfer apparatus.

The remediation 72-3 is operative in response to a determination that oblique insertion or removal of a wafer into or from the FOUP 18 has occurred, and includes stopping the wafer transfer and outputting a notification of the detection. The remediation of stopping the wafer transfer immediately is appropriate since continuing the transfer during/after oblique insertion or removal of a wafer has a high likelihood of destroying the wafer and/or damaging the FOUP 18.

Since the approach of FIG. 5 provides information on the type of problem with the wafer transfer (collision, wafer scratch, or oblique insertion/removal), the notifications included in the remediation actions 72-1, 72-2, and 72-3 may optionally include identifying the type of problem detected. The remediation actions 72-1, 72-2, and 72-3 are merely nonlimiting illustrative examples, and different types of remediation are also contemplated. For example, in a variant embodiment the remediation 72-2 may also include stopping the wafer transfer.

In the following, some further embodiments are described.

In a nonlimiting illustrative embodiment, a semiconductor wafer transfer monitoring apparatus is operative in conjunction with an associated semiconductor wafer transfer apparatus. The semiconductor wafer transfer monitoring apparatus comprises: a vibration sensor operatively connected to measure vibration data of a component of the associated semiconductor wafer transfer apparatus during a semiconductor wafer transfer performed by the associated semiconductor wafer transfer apparatus; and an electronic processor programmed to analyze the measured vibration data to detect a problem with the semiconductor wafer transfer, and to perform at least one remedial action in response to detection of the problem with the semiconductor wafer transfer.

In a nonlimiting illustrative embodiment, a semiconductor wafer transfer monitoring method comprises: measuring vibration of a component during a transfer of a semiconductor wafer; analyzing the measured vibration to detect a collision or scratching of the semiconductor wafer during the transfer; and performing at least one remedial action in response to the detection of the collision or scratching of the semiconductor wafer.

In a nonlimiting illustrative embodiment, a semiconductor wafer transfer apparatus includes: a wafer transfer robot configured to transfer semiconductor wafers between a wafer carrier and a semiconductor wafer processing or characterization tool; a vibration sensor configured to measure vibration of the wafer transfer robot; and an electronic processor programmed to detect a problem with a transfer of a semiconductor wafer performed by the wafer transfer robot by analyzing vibration of the wafer transfer robot measured by the vibration sensor during the transfer.

In a nonlimiting illustrative embodiment, semiconductor wafer transfer monitoring includes measuring vibration of a component during a transfer of a semiconductor wafer. The measured vibration is analyzed to detect a collision or scratching of the semiconductor wafer during the transfer. At least one remedial action is performed in response to the detection of the collision or scratching of the semiconductor wafer, such as outputting a notification of the collision or scratching, or stopping the transfer of the semiconductor wafer. The component whose vibration is measured may be a wafer transfer robot used in the transfer. The analysis of the measured vibration may include inputting the measured vibration to an artificial intelligence (AI) algorithm trained to detect the collision or scratching of the semiconductor wafer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor wafer transfer monitoring apparatus operative in conjunction with an associated semiconductor wafer transfer apparatus, the semiconductor wafer transfer monitoring apparatus comprising:
a vibration sensor operatively connected to measure vibration data of a component of the associated semiconductor wafer transfer apparatus during a semiconductor wafer transfer performed by the associated semiconductor wafer transfer apparatus; and
an electronic processor programmed to analyze the measured vibration data to detect a problem with the semiconductor wafer transfer, and to perform at least one remedial action in response to detection of the problem with the semiconductor wafer transfer.

2. The semiconductor wafer transfer monitoring apparatus of claim 1, wherein the at least one remedial action includes stopping the semiconductor wafer transfer being performed by the associated semiconductor wafer transfer apparatus.

3. The semiconductor wafer transfer monitoring apparatus of claim 1, wherein the at least one remedial action includes outputting an alert indicating the problem.

4. The semiconductor wafer transfer monitoring apparatus of claim 1, wherein the electronic processor is programmed to analyze the measured vibration data to detect the problem with the semiconductor wafer transfer by inputting the measured vibration data to an artificial intelligence (AI) algorithm trained to detect the problem with the semiconductor wafer transfer.

5. The semiconductor wafer transfer monitoring apparatus of claim 1, wherein the electronic processor is programmed to analyze the measured vibration data to detect the problem with the semiconductor wafer transfer by comparing the measured vibration data with reference vibration data representing successful semiconductor wafer transfer.

6. The semiconductor wafer transfer monitoring apparatus of claim 1, wherein the vibration sensor is operatively connected to measure vibration data of a wafer transfer robot of the associated semiconductor wafer transfer apparatus.

7. The semiconductor wafer transfer monitoring apparatus of claim 6, wherein the vibration sensor is disposed on the wafer transfer robot, and the vibration sensor includes a wireless transmitter or transceiver configured to wirelessly transfer the measured vibration data to the electronic processor.

8. The semiconductor wafer transfer monitoring apparatus of claim 1, wherein the vibration sensor comprises an accelerometer.

9. The semiconductor wafer transfer monitoring apparatus of claim 1, wherein the electronic processor is programmed to analyze the vibration data to detect the problem with the semiconductor wafer transfer comprising a collision of a semiconductor wafer being transferred by the semiconductor wafer transfer.

10. The semiconductor wafer transfer monitoring apparatus of claim 1, wherein the electronic processor is programmed to analyze the vibration data to detect the problem with the semiconductor wafer transfer comprising formation of at least one scratch on a semiconductor wafer being transferred by the semiconductor wafer transfer.

11. The semiconductor wafer transfer monitoring apparatus of claim 1, wherein the electronic processor is programmed to analyze the vibration data to detect the problem with the semiconductor wafer transfer comprising oblique insertion or removal of a semiconductor wafer being transferred by the semiconductor wafer transfer into or from a wafer storage slot.

12. The semiconductor wafer transfer monitoring apparatus of claim 1, wherein the electronic processor is further programmed to:
receive control data relating to the semiconductor wafer transfer;
determine, from the control data, a stage of the semiconductor wafer transfer at a time of the problem with the semiconductor wafer transfer; and
classify the problem with the semiconductor wafer transfer based at least in part on the determined stage of the semiconductor wafer transfer at the time of the problem with the semiconductor wafer transfer.

13. The semiconductor wafer transfer monitoring apparatus of claim 12, wherein the electronic processor is programmed to receive the control data relating to the semiconductor wafer transfer from the associated semiconductor wafer transfer apparatus.

14. A semiconductor wafer transfer monitoring method comprising:
measuring vibration of a component during a transfer of a semiconductor wafer;
analyzing the measured vibration to detect a collision or scratching of the semiconductor wafer during the transfer; and
performing at least one remedial action in response to the detection of the collision or scratching of the semiconductor wafer.

15. The semiconductor wafer transfer monitoring method of claim 14, wherein the analyzing comprises inputting the measured vibration to an artificial intelligence (AI) algorithm trained to detect the collision or scratching of the semiconductor wafer.

16. The semiconductor wafer transfer monitoring method of claim 14, wherein the vibration of the component is measured using an accelerometer.

17. The semiconductor wafer transfer monitoring method of claim 14, further comprising:
performing the transfer of the semiconductor wafer using a wafer transfer robot;
wherein the measuring comprises measuring vibration of the wafer transfer robot.

18. The semiconductor wafer transfer monitoring method of claim 14, further comprising:
determining a stage of the transfer of the semiconductor wafer at a time of the detection of the collision or scratching of the semiconductor wafer; and
classifying the collision or scratching of the semiconductor wafer based at least in part based on the determined stage of the semiconductor wafer transfer at the time of the detection of the collision or scratching of the semiconductor wafer.

19. A semiconductor wafer transfer apparatus comprising:
a wafer transfer robot configured to transfer semiconductor wafers between a wafer carrier and a semiconductor wafer processing or characterization tool;
a vibration sensor configured to measure vibration of the wafer transfer robot; and
an electronic processor programmed to detect a problem with a transfer of a semiconductor wafer performed by the wafer transfer robot by analyzing vibration of the wafer transfer robot measured by the vibration sensor during the transfer.

20. The semiconductor wafer transfer apparatus of claim 19, wherein the vibration sensor is disposed on the wafer transfer robot and the vibration sensor includes:
a wireless transceiver or transmitter configured to transmit the measurement of the vibration of the wafer transfer robot from the vibration sensor to the electronic processor.
